(19) United States
(12) Patent Application Publication
(10) Pub. No.: US 2006/0180136 A1
(43) Pub. Date: Aug. 17, 2006

(54) Tape expansion apparatus

(75) Inventors: Yusuke Nagai, Tokyo (JP); Naoki Ohmiya, Tokyo (JP); Kentaro Iizuka, Tokyo (JP)

Correspondence Address: SMITH, GAMBRELL & RUSSELL, LLP, 1850 M STREET, N.W., SUITE 800, WASHINGTON, DC, 20036, US

(73) Assignee: Disco Corporation

(21) Appl. No.: 11/091,404

(22) Filed: Mar. 29, 2005

(30) Foreign Application Priority Data
Mar. 31, 2004 (JP) 2004-106279

(51) Int. Cl. H01L 21/687

(52) U.S. Cl. 125/35; 269/56

(57) ABSTRACT

A tape expansion apparatus for expanding a holding tape, which is mounted on an annular frame and to which a wafer having a plurality of areas sectioned by a plurality of dividing lines is affixed, comprising a frame holding means for holding the annular frame; a plurality of tape holding means for nipping an area between the inner periphery of the annular frame and the wafer of the holding tape mounted on the annular frame held on the frame holding means; and a tape expansion means for moving the plurality of tape holding means in radial directions.

### FIELD OF THE INVENTION

The present invention relates to a tape expansion apparatus for expanding a holding tape, which is mounted on an annular frame and to which a wafer having a plurality of areas sectioned by a plurality of dividing lines has been affixed.

### DESCRIPTION OF THE PRIOR ART

In the production process of a semiconductor device, a plurality of areas are sectioned by dividing lines called “streets” arranged in a lattice pattern on the front surface of a substantially disk-like semiconductor wafer and a circuit such as IC, LSI or the like is formed in each of the sectioned areas. Individual semiconductor chips are manufactured by cutting this semiconductor wafer along the dividing lines to divide it into the areas having a circuit formed thereon. An optical device wafer comprising gallium nitride-based compound semiconductors laminated on the front surface of a sapphire substrate is also cut along dividing lines to be divided into individual optical devices such as light emitting diodes or laser diodes, which are widely used in electric equipment.

Cutting along the dividing lines of the above semiconductor wafer or optical device wafer is generally carried out by using a cutting machine called “dicer”. This cutting machine comprises a chuck table for holding a workpiece such as a semiconductor wafer or optical device wafer, a cutting means for cutting the workpiece held on the chuck table, and a cutting-feed means for moving the chuck table and the cutting means relative to each other. The cutting means has a rotary spindle, a cutting blade mounted on the spindle and a drive unit for rotary-driving the rotary spindle. The cutting blade is composed of a disk-like base and an annular cutting-edge which is mounted on the side wall outer peripheral portion of the base and formed as thick as about 20 μm by fixing diamond abrasive grains having a diameter of about 3 μm to the base by electroforming.

Since a sapphire substrate, silicon carbide substrate, etc. have high Mohs hardness, however, cutting with the above cutting blade is not always easy. Further, as the cutting blade has a thickness of about 20 am, the dividing lines for sectioning devices must have a width of about 50 μm. Therefore, in the case of a device measuring 300 μm×300 μm, the area ratio of the streets to the wafer becomes 14%, thereby reducing productivity.

Meanwhile, as a means of dividing a plate-like workpiece such as a semiconductor wafer, a laser processing method for applying a pulse laser beam capable of passing through the workpiece with its focusing point set to the inside of the area to be divided is also attempted nowadays. In the dividing method making use of this laser processing technique, the workpiece is divided by applying a pulse laser beam of an infrared range capable of passing through the workpiece from one side of the workpiece with its focusing point set to the inside to continuously form a deteriorated layer along the dividing lines in the inside of the workpiece and exerting external force along the dividing lines whose strength has been reduced by the formation of the deteriorated layers. This method is disclosed by Japanese Patent No. 3408805.

As a means of dividing a wafer into individual chips by exerting external force along the dividing lines of the wafer having deteriorated layers continuously formed along the dividing lines as described above, the applicant company proposed a technology for dividing a wafer into individual chips by expanding a holding tape to which the wafer has been affixed, to apply tensile force to the wafer as Japanese Patent Application No. 2003-361471.

However, in the method of expanding the holding tape to which the wafer has been affixed, to apply tensile force to the wafer, there occurs a case where tensile force is not fully transmitted to all the area of the wafer and the wafer is not divided along all of the dividing lines. Therefore, this method is unsatisfactory in terms of reliability.

### SUMMARY OF THE INVENTION

It is an object of the present invention to provide a tape expansion apparatus capable of dividing a wafer whose strength has been reduced along the dividing lines efficiently and surely.

According to the present invention, the above object of the present invention can be attained by a tape expansion apparatus for expanding a holding tape which is mounted on an annular frame and to which a wafer having a plurality of areas sectioned by a plurality of dividing lines has been affixed, comprising:

a frame holding means for holding the annular frame;

a plurality of tape holding means for nipping an area between the inner periphery of the annular frame and the wafer of the holding tape mounted on the annular frame held on the frame holding means; and

a tape expansion means for moving the plurality of tape holding means in radial directions.

The above frame holding means has a plurality of support columns and an annular frame holding member that is mounted on the upper ends of the plurality of support columns and has a placing surface for placing the annular frame. Preferably, the frame holding means is so constituted to allow the annular frame holding member to turn on the plurality of support columns and has a turning means for turning the annular frame holding member. The plurality of tape holding means are arranged at equal angles to each other in the peripheral direction.

In the tape expansion apparatus constituted according to the present invention, the area between the inner periphery of the annular frame and the wafer in the holding tape to which the wafer is affixed is nipped by the plurality of tape holding means, and the plurality of tape holding means are moved in radial directions by the tape expansion means. Therefore, tensile force acting on the holding tape can be fully transmitted to all the areas of the wafer. Consequently, by using the tape expansion apparatus of the present invention, the wafer whose strength has been reduced along the dividing lines can be divided along the dividing lines efficiently and surely.

### BRIEF DESCRIPTION OF THE DRAWINGS

FIG. 1 is a perspective view of an embodiment of a tape expansion apparatus constituted according to the present invention;

FIG. 2 is an exploded perspective view of the constituent members of the tape expansion apparatus shown in FIG. 1;

FIGS. 3(a) and 3(b) are diagrams respectively showing a state where an annular frame is held on a frame holding member constituting the tape expansion apparatus shown in FIG. 1 and a state where the holding tape mounted on the annular frame held on the frame holding member is nipped by tape holding means;

FIG. 4 is a diagram showing a state where the expansion means constituting the tape expansion apparatus shown in FIG. 1 are activated to expand the holding tape;

FIG. 5 is a perspective view of a tape expansion apparatus according to another embodiment of the present invention;

FIG. 6 is a sectional view of the principal section of frame holding means constituting the tape expansion apparatus shown in FIG. 5;

FIG. 7 is a diagram showing a state where expansion means constituting the tape expansion apparatus shown in FIG. 5 are activated to expand the holding tape;

FIG. 8 is a side view of the principal section of another example of tape holding means constituting the tape expansion apparatus of the present invention;

FIG. 9 is a perspective view of a wafer whose strength has been reduced along the dividing lines, is affixed to the holding tape mounted on the annular frame; and

FIGS. 10(a), 10(b) and 10(c) are perspective views showing the step of affixing the wafer whose strength has been reduced along the dividing lines to the holding tape mounted on the annular frame.

### DETAILED DESCRIPTION OF THE PREFERRED EMBODIMENTS

Preferred embodiments of the present invention will be described hereinunder with reference to the accompanying drawings.

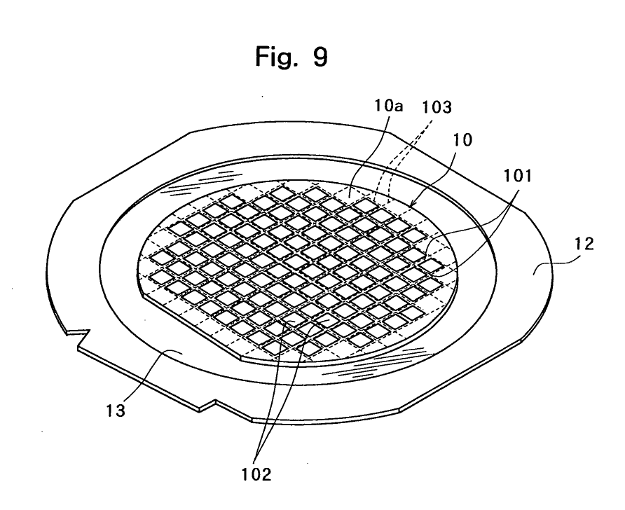

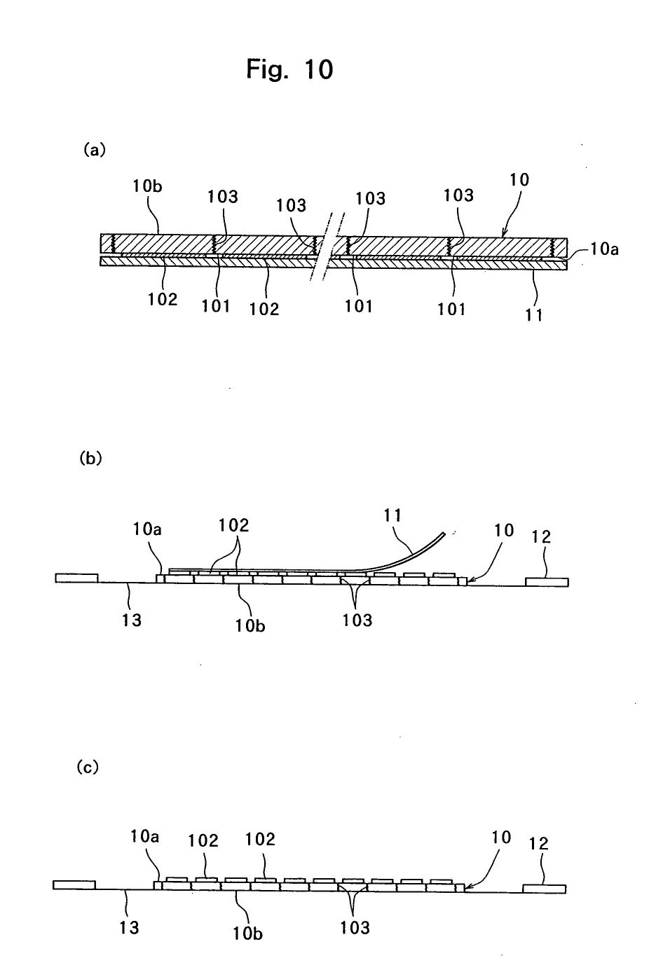

To divide a wafer whose strength has been reduced along the dividing lines, the wafer 10 is put on the top surface of an elastic holding tape 13 mounted on an annular frame 12 in such a manner that its front surface 10a faces up, so that it is supported on the annular frame 12, as shown in FIG. 9. The step of putting the wafer 10 whose strength has been reduced along the dividing lines, on the top surface of the holding tape 13 mounted on the annular frame 12 will be described with reference to FIGS. 10(a) to 10(c).

As shown in FIG. 9 and FIG. 10(a), the wafer 10 in the illustrated embodiment is a semiconductor wafer having a plurality of dividing lines 101 formed in a lattice pattern on the front surface 10a and a circuit 102 formed in each of a plurality of areas sectioned by the plurality of dividing lines 101. As shown in FIG. 10(a), a protective member 11 is mounted on the front surface 10a of this wafer 10 and a deteriorated layer 103 is formed along the dividing lines 101 by applying a pulse laser beam capable of passing through the wafer with its focusing point set to the inside along the dividing lines 101, from the back surface 10b side. The strength of the wafer 10 is reduced along the dividing lines 101 by the formation of the deteriorated layers 103. The wafer 10 whose strength has been thus reduced along the dividing lines 101 is put on the above holding tape 13 in such a manner that the back surface 10b side comes into contact with the top surface of the holding tape 13, as shown in FIG. 10(b). And, by removing the protective member 11 from the front surface 10a of the wafer 10, the wafer 10 whose strength has been reduced along the dividing lines 101 by the formation of the deteriorated layers 103, as shown in FIG. 10(c), is put on the top surface of the holding tape 13 mounted on the annular frame 12 in such a manner that the front surface 10a faces up.

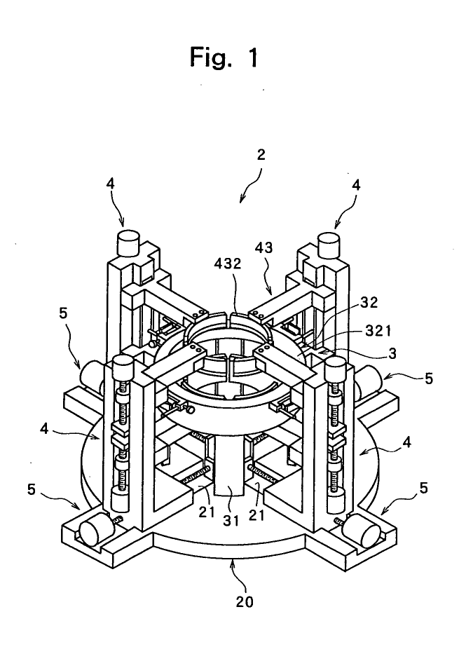

A description will be subsequently given of a tape expansion apparatus for dividing the above-described wafer 10 along the dividing lines 101 with reference to FIGS. 1 to 4.

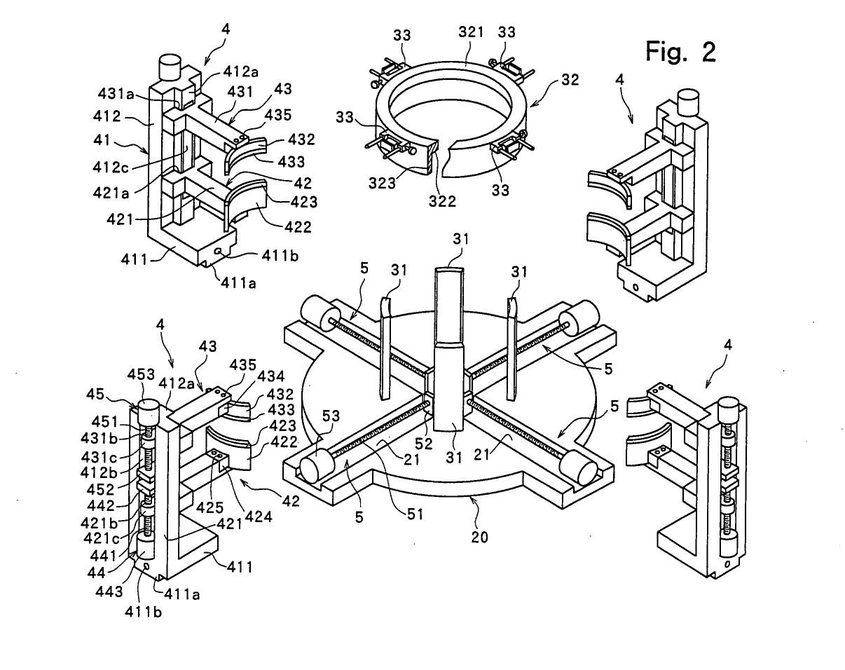

FIG. 1 is a perspective view of a tape expansion apparatus constituted according to an embodiment of the present invention and FIG. 2 is an exploded perspective view of the tape expansion apparatus shown in FIG. 1.

The tape expansion apparatus 2 in this embodiment shown in FIG. 1 and FIG. 2 comprises a fixed base 20, frame holding means 3 that is installed on the top surface of the center portion of the fixed base 20 and holds the annular frame 12, a plurality (four in the illustrated embodiment) of tape holding means 4 for nipping the above holding tape 13 mounted on the annular frame 12 held on the frame holding means 3 and a plurality (four in the illustrated embodiment) of tape expansion means 5 for moving the plurality of tape holding means 4 in the respective radial directions.

The above fixed base 20 is formed like a disk, and guide grooves 21 and 21 crossing each other at right angles and passing through the center are formed in the top surface of the fixed base 20. Peripheral portions where the above guide grooves 21 and 21 of the fixed base 20 are formed project outward. The above frame holding means 3 comprises four support columns 31 installed on the top surface of the fixed base 20 and an annular frame holding member 32 mounted on the upper ends of the four support columns 31. The four support columns 31 are arranged between the guide grooves 21 and 21 formed in the fixed base 20. The annular frame holding member 32 is formed substantially as large as the above annular frame 12, and its top surface serves as a placing surface 321 for placing the annular frame 12. This frame holding member 32 has a cross section in the shape of an inverted L-letter as shown in FIG. 2, a to-be-supported surface 322 parallel to the above placing surface 321 and a restricting portion 323 hanging down from its outer periphery. The frame holding member 32 is provided with four clamps 33 arranged at equal angles to each other in the peripheral direction. The to-be-supported surface 322 of the frame holding member 32 constituted as described above is placed on the upper end faces of the four support columns 31, and fixed by a fixing means that is not shown.

The above four tape holding means 4 are installed on the respective guide grooves 21 and 21 formed in the above fixed base 20. That is, the four tape holding means 4 are arranged at equal angles to each other in the peripheral direction. Each of the thus arranged tape holding means 4 has an L-shaped movable base 41, a first nipping means 42 and a second nipping means 43, both mounted onto the movable base 41 in such a manner that they can move in the vertical direction, and a first moving means 44 and a second moving means 45 for moving the first nipping means 42 and the second nipping means 43 in the vertical direction, respectively. The movable base 41 consists of a moving portion 411 and a support portion 412 projecting upward from the top of the moving portion 411. A to-be-guided rail 411a to be fitted to the guide groove 21 is formed on the undersurface of the moving portion 411. By fitting the to-be-guided rail 411a to the guide groove 21, the movable base 41 is constituted to be allowed to move in the radial direction along the guide groove 21 of the disk-like fixed base 20. A female screw 411b is formed in the moving portion 411 in such a manner that it penetrates through the moving portion 411. A guide rail 412a extending in the vertical direction is formed on the inner surface (surface facing each other), and a prolonged groove 412b extending in the vertical direction is formed in the outer surface of the support portion 412. A prolonged hole 412c extending in the vertical direction and reaching the prolonged groove 412b from the inner surface is formed in the guide rail 412a.

The above first nipping means 42 comprises a support arm 421 which can move along the guide rail 412a formed on the support portion 412 of the above movable base 41 and a nipping member 422 attached to the support arm 421. A to-be-guided groove 421a to be fitted to the above guide rail 412a is formed at the proximal end of the support arm 421, and the support arm 421 is constituted to be allowed to move in the vertical direction along the guide rail 412a of the support portion 412 of the movable base 41 by fitting the guide groove 421a to the guide rail 412a. The proximal portion of the support arm 421 is provided with a female screw block 421c having a female screw 421b which is inserted into the above prolonged hole 412c. The above nipping member 422 has a slightly larger curvature radius than the radius of the above wafer 10, and a friction member 423 having a large friction coefficient, such as rubber is mounted on its upper end face (face opposed to the nipping member of the second nipping means 43 that will be described later). An attachment member 424 is fixed to the back surface of the nipping member 422 and detachably attached to the distal end of the support arm 431 by screws 425.

The above second nipping means 43 comprises a support arm 431 that can move along the guide rail 412a on the support portion 412 of the above movable base 41 and a nipping member 432 attached to the support arm 431. A to-be-guided groove 431a to be fitted to the above guide rail 412a is formed at the proximal end of the support arm 431, and the support arm 431 is constituted to be allowed to move in the vertical direction along the guide rail 412a of the support portion 412 of the movable base 41 by fitting the guide groove 431a to the guide rail 412a. The proximal portion of the support arm 431 is provided with a female screw block 431c having a female screw 431b which is inserted into the above prolonged hole 412c. The above nipping member 432 has a slightly larger curvature radius than the radius of the above wafer 10, and a plastic member 433 made of polytetrafluoroethylene is mounted on its lower end face (face opposed to the nipping member 422 of the above first nipping means 42) to prevent the adhesion of adhesive applied on the surface of the holding tape 13. An attachment member 434 is fixed to the back surface of the nipping member 432 and detachably mounted to the distal end of the support arm 431 by screws 435.

The first moving means 44 for moving the above first nipping means 42 in the vertical direction comprises a male screw rod 441 which is screwed into the female screw 421b of the female screw block 421c that is provided at the proximal portion of the above support arm 421 and arranged parallel to the guide rail 412a in the prolonged groove 412b formed in the support portion 412 of the above movable base 41, a bearing 442 that is mounted on the support portion 412 of the movable base 41 and rotatably supports one end of the male screw rod 441, and a pulse motor 443 for rotary-driving the male screw rod 441, which is connected to the other end of the male screw rod 441. The pulse motor 443 of the thus constituted first moving means 44 is activated to turn the male screw rod 441, thereby moving the first nipping means 42 in the vertical direction along the guide rail 412a.

The second moving means 45 for moving the above second nipping means 43 in the vertical direction is the same in constitution as the above first moving means 44 and arranged above the first moving means 44. That is, the second moving means 45 comprises a male screw rod 451 which is screwed into the female screw 431b of the female screw block 431c that is provided at the proximal portion of the above support arm 431 and arranged parallel to the guide rail 412a in the prolonged groove 412b formed in the support portion 412 of the above movable base 41, a bearing 452 that is mounted on the support portion 412 of the movable base 41 and rotatably supports one end of the male screw rod 451, and a pulse motor 453 for rotary-driving the male screw rod 451, which is connected to the other end of the male screw rod 451. The pulse motor 453 of the thus constituted second moving means 45 is activated to turn the male screw rod 451, thereby moving the second nipping means 43 along the guide rail 412a in the vertical direction.

The four tape expansion means 5 for moving the above four tape holding means 4 in each of the radial directions are arranged along the guide grooves 21 and 21 of the above fixed base 20. Each of the tape expansion means 5 comprises a male screw rod 51 which is arranged parallel to the guide groove 21 and is screwed into the female screw 411b formed in the moving portion 411 of the above movable base 41, a bearing 52 that is mounted on the fixed base 20 and rotatably supports one end of the male screw rod 51, and a pulse motor 53 for rotary-driving the male screw rod 51, which is connected to the other end of the male screw rod 51. The pulse motor 53 of the thus constituted tape expansion means 5 is activated to turn the male screw rod 51, thereby moving the tape holding means 4 in the respective radial direction.

The tape expansion apparatus 2 in the embodiment shown in FIG. 1 and FIG. 2 is constituted as described above, and its function will be described hereinbelow.

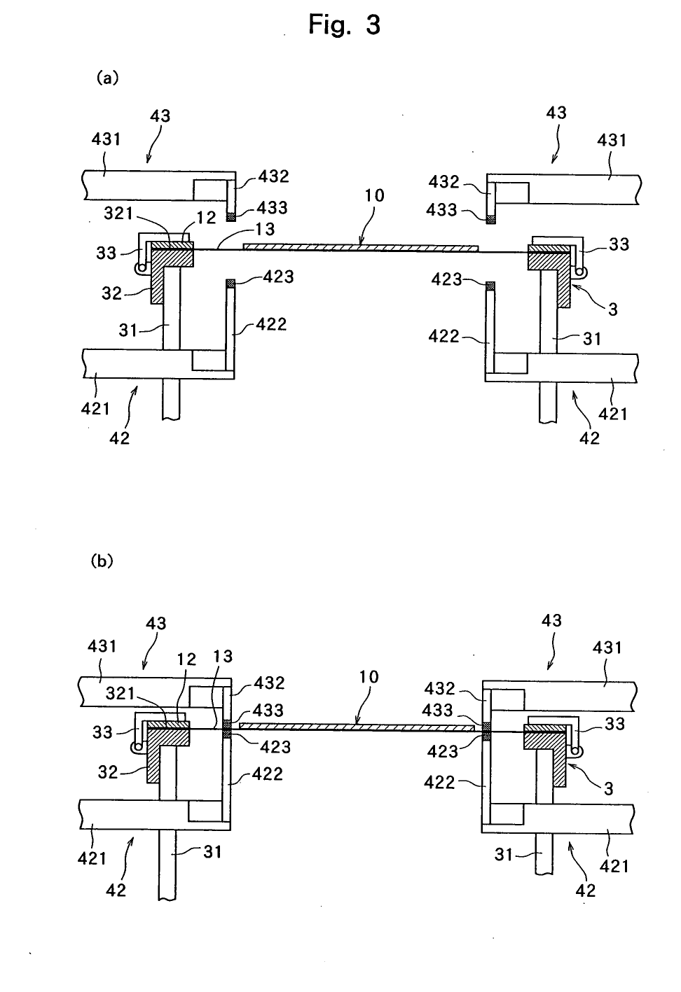

The annular frame 12 supporting the semiconductor wafer 10 whose strength has been reduced along the dividing lines 101 via the holding tape 13 as shown in FIG. 9 is placed on the placing surface 321 of the annular frame holding member 32 constituting the above frame holding means 3 as shown in FIG. 3(a), and fixed to the frame holding member 32 by the clamps 33. At this point, the first nipping means 42 and the second nipping means 43 constituting the tape holding means 4 are located at stand-by positions shown in FIG. 3(a).

After the annular frame 12 holding the semiconductor wafer 10 via the holding tape 13 is held on the frame holding member 32, the first moving means 44 and the second moving means 45 for moving the first nipping means 42 and the second nipping means 43 constituting the tape holding means 4 in the vertical direction are activated to move up the first nipping means 42 and move down the second nipping means 43, respectively. As a result, as shown in FIG. 3(b), the area between the inner periphery of the annular frame 12 and the semiconductor wafer 10 in the holding tape 13 is nipped by the friction member 423 attached to the nipping member 422 constituting the first nipping means 42 and the friction member 433 attached to the nipping member 432 constituting the second nipping means 43.

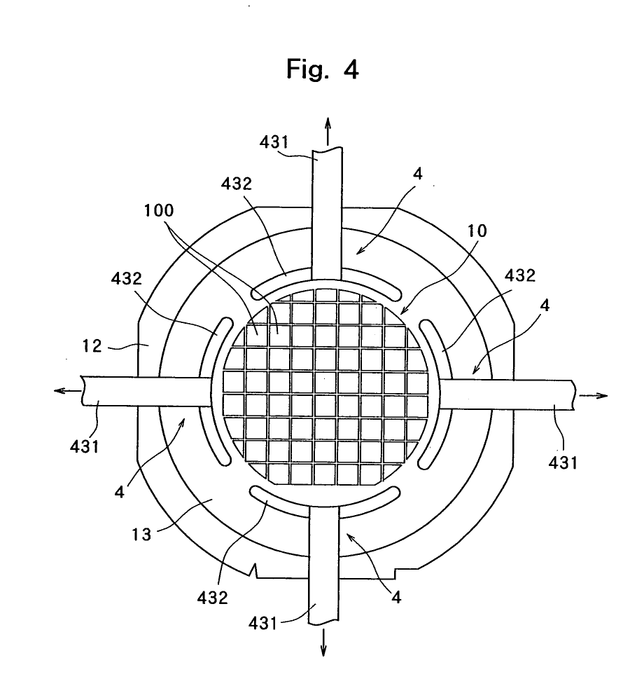

After the holding tape 13 is nipped by the four tape holding means 4 as described above, the above tape expansion means 5 are activated to move the four tape holding means 4 outward in radical directions. Accordingly, the holding tape 13 mounted on the annular frame 12 is expanded radially by the four tape holding means 4, as shown in FIG. 4. At this moment, in the illustrated embodiment, as the holding tape 13 is nipped by the friction members 423 and 433 attached to the nipping members 422 and 432, force applied to the tape holding means 4 can be transmitted to the holding tape 13 surely. As a result, tensile force is applied radially to the semiconductor wafer 10 affixed to the holding tape 13. When tensile force acts radially on the semiconductor wafer 10, as the deteriorated layers 103 formed along the dividing lines 101 have reduced strength, the semiconductor wafer 10 is divided into individual semiconductor chips 100 along the deteriorated layers 103. According to experiments conducted by the inventors of the present invention, when the holding tape 13 was elongated about 5 mm, the semiconductor wafer 10 could be divided along the deteriorated layers 103. Since the semiconductor wafer can be divided with such a small amount of elongation, the slack of the holding tape 13 can be reduced. Thereafter, the semiconductor chips 100 are picked up by the pick-up collet of a pick-up means (not shown), and carried to a tray or die bonding step that is not shown.

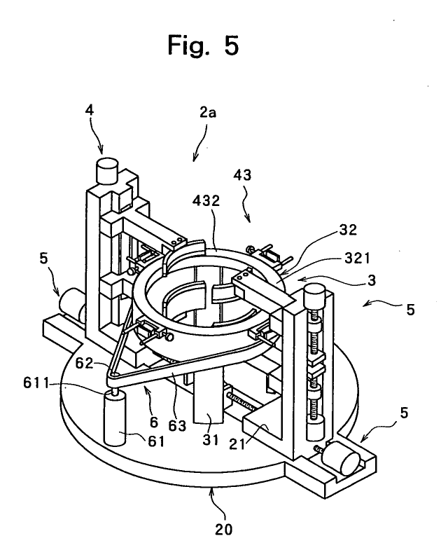

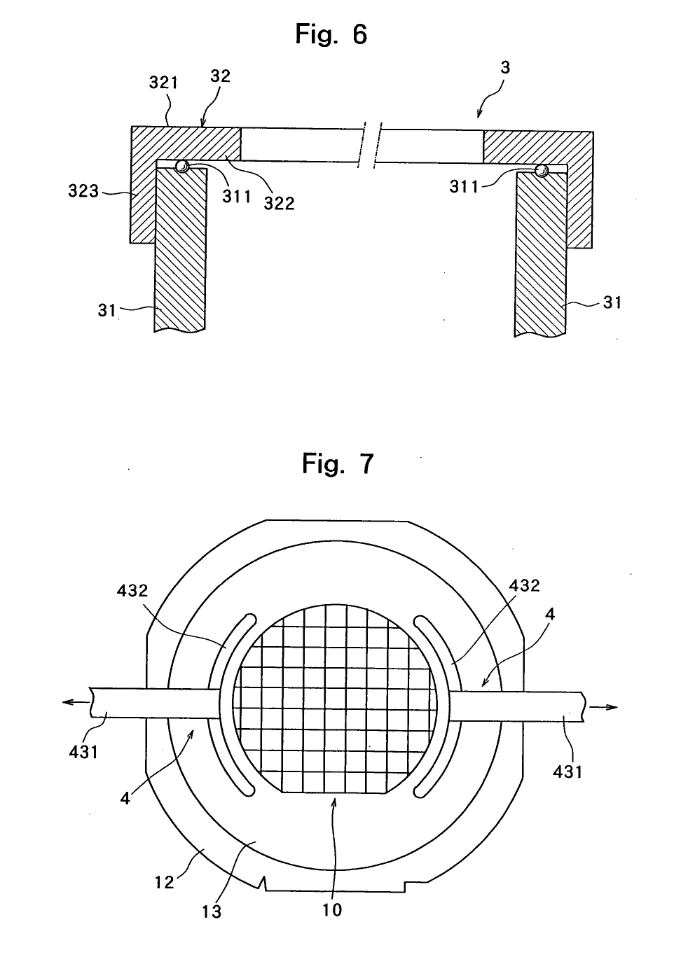

A description will be subsequently given of a tape expansion apparatus according to another embodiment of the present invention with reference to FIG. 5 and FIG. 6. In the tape expansion apparatus shown in FIG. 5 and FIG. 6, the same members as the constituent members shown in FIGS. 1 to 4 are given the same reference numerals and their detailed descriptions are omitted.

The tape expansion apparatus 2a in the embodiment shown in FIG. 5 and FIG. 6 comprises two tape holding means 4, and the annular frame holding member 32 constituting the frame holding means 3 is so constructed to be able to turn. That is, the two tape holding means 4 and 4 are opposed to each other. Further, as shown in FIG. 6, a ball bearing 311 is installed on the upper ends of the respective four support columns 31 constituting the frame holding means 3, and the to-be-supported surface 322 of the annular frame holding member 32 is placed on the ball bearing 311 so that the frame holding member 32 is turnably supported on the four support columns 31. Since the restricting portion 323 of the frame holding member 32 placed on the four support columns 31 is positioned on the external sides of the four support columns 31, the movement to the horizontal direction of the frame holding member 32 is restricted.

The tape expansion apparatus 2a in the illustrated embodiment has a turning means 6 for turning the above frame holding member 32, as shown in FIG. 5. This turning means 6 comprises a pulse motor 61 installed on the above fixed base 20, a pulley 62 mounted onto the drive shaft 611 of the pulse motor 61, and an endless belt 63 wound round the pulley 62 and the outer peripheral wall of the frame holding member 32.

The tape expansion apparatus 2a in the embodiment shown in FIG. 5 and FIG. 6 is constituted as described above, and its function will be described hereinbelow.

The operation of holding the annular frame 12 supporting the semiconductor wafer 10 whose strength has been reduced along the dividing lines 101 on the frame holding means 3 and nipping the holding tape 13 by using the tape holding means 4 is the same as in the embodiment shown in FIGS. 1 to 4. The tape expansion means 5 are activated to move the two tape holding means 4 outward in radial directions indicated by arrows in FIG. 7. Accordingly, the holding tape 13 mounted on the annular frame 12 is expanded in the directions indicated by the arrows in FIG. 7 (first expansion step). As a result, tensile force acts on the semiconductor wafer 10 affixed to the holding tape 13 in the directions indicated by the arrows in FIG. 7 to divide the semiconductor wafer 10 along some of the dividing lines 101. Then, the above tape holding means 4 is activated to release the holding tape 13 from the nipping, and the turning means 6 is activated to turn the frame holding means 32 at 90°. The holding tape 13 is then nipped by two tape holding means 4 again. Thereafter, the tape expansion means 5 are activated to expand the holding tape 13 in directions perpendicular to the expansion directions of the above first expansion step (second expansion step). As a result, the semiconductor wafer 10 affixed to the holding tape 13 is divided into individual semiconductor chips along the dividing lines 101, along which the semiconductor wafer 10 was not divided in the first expansion step.

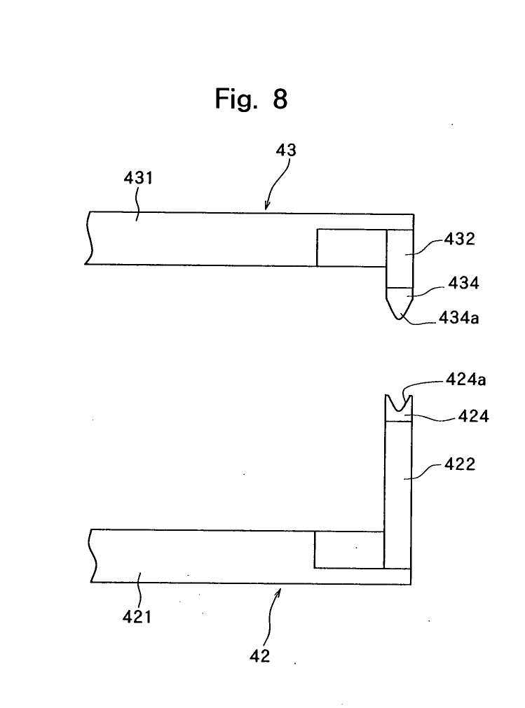

A description will be subsequently given of another embodiment of a member attached to the upper end face of the nipping member 422 constituting the first nipping means 42 and a member attached to the lower end face of the nipping member 432 constituting the second nipping means 43 of the above tape holding means 4 with reference to FIG. 8.

In the embodiment shown in FIG. 8, a first plastic member 424 made of polytetrafluoroethylene and the like is mounted onto the upper end face of the nipping member 422 constituting the first nipping means 42, and a second plastic member 434 made of polytetrafluoroethylene and the like is mounted onto the lower end face of the nipping member 432 constituting the second nipping means 43. A V-shaped recessed portion 424a is formed in the top surface of the first plastic member 424 and a projecting portion 434a to be fitted to the recessed portion 424a is formed at the lower end of the second plastic member 434. Therefore, in the tape holding means 4 shown in FIG. 8, the holding tape 13 is nipped between the recessed portion 424a of the first plastic member 424 and the projecting portion 434a of the second plastic member 434.

Having described the invention as related to the embodiments shown in the accompanying drawings, it should be understood that the invention be not limited to these embodiments and that various changes may be made on the invention without departing from the spirit and scope of the invention. For example, in the above embodiments, the male screw rods and the pulse motors are used as the moving means for moving the nipping means of the tape holding means and the tape expansion means. A drive mechanism such as an air cylinder mechanism may be employed. In the above embodiments, the wafer whose strength has been reduced along the dividing lines is divided along the dividing lines by the tape expansion apparatus of the present invention. The tape expansion apparatus of the present invention may be used as an expansion apparatus for expanding the interval (gap) between chips when individual chips are picked up after the wafer is divided along the dividing lines by a dicer or scriber.

What is claimed is:

1. A tape expansion apparatus for expanding a holding tape, which is mounted on an annular frame and to which a wafer having a plurality of areas sectioned by a plurality of dividing lines is affixed, comprising:
a frame holding means for holding the annular frame;
a plurality of tape holding means for nipping an area between the inner periphery of the annular frame and the wafer of the holding tape mounted on the annular frame held on the frame holding means; and
a tape expansion means for moving the plurality of tape holding means in radial directions.

2. The tape expansion apparatus according to claim 1, wherein the frame holding means comprises a plurality of support columns and an annular frame holding member that is mounted on the upper ends of the plurality of support columns and has a placing surface for placing the annular frame.

3. The tape expansion apparatus according to claim 2, wherein the frame holding means is so constituted to allow the annular frame holding member to turn on the plurality of support columns and has a turning means for turning the annular frame holding member.

4. The tape expansion apparatus according to claim 1, wherein the plurality of tape holding means are arranged at equal angles to each other in the peripheral direction.
